(19) United States
(12) Patent Application Publication
(10) Pub. No.: US 2016/0359139 A1
(43) Pub. Date: Dec. 8, 2016

(54) MOISTURE ABSORBING MEMBRANE, WATERPROOF MEMBRANE, AND ORGANIC EL DEVICE

(71) Applicant: PANASONIC CORPORATION, Kadoma-shi (JP)

(72) Inventors: Yoichi SHINTANI, Osaka (JP); Tatsuhiro TOMIYAMA, Miyagi (JP); Yasutaka TSUTSUI, Osaka (JP); Akira KAWASE, Osaka (JP); Iwao UENO, Kyoto (JP)

(21) Appl. No.: 15/116,581

(22) PCT Filed: Mar. 6, 2015
(86) PCT No.: PCT/JP2015/001228

§ 371 Date: Aug. 4, 2016

(30) Foreign Application Priority Data
Mar. 7, 2014 (JP) 2014-045670
Jul. 2, 2014 (JP) PCT/JP2014/003534

(51) Int. Cl. H01L 51/52

(52) U.S. Cl. CPC H01L 51/5259; H01L 51/5253; H01L 2251/558; H01L 2251/5338

(57) ABSTRACT

A moisture sorption film including: a film of base material; zeolite grains dispersed in the film of base material, having an average diameter of 100 nm or smaller, and having a maximum moisture sorption ratio of 10 wt % or greater. The moisture sorption film has a thickness of 500 nm or greater and contains the zeolite grains at an amount of 0.13 g/cm³ or greater.

### TECHNICAL FIELD

The present invention relates to moisture sorption films, water-resisting films including moisture sorption films, and organic electro luminescence (EL) devices including moisture sorption films.

### BACKGROUND ART

Conventionally, moisture sorption films containing grains of a desiccant (e.g., silica gel or quicklime (calcium oxide)) dispersed in a base member (e.g., a resin) are widely used to maintain items, such as electronic devices, building materials, and food products, in desirable state. Moisture sorption films are typically either included in such items or provided in the form of packaging for such items. Further, films that are resistant to penetration by moisture (referred to in the following as water-resisting films) can be produced by enclosing the moisture sorption films with inorganic films with low water vapor transmission rate (WVTR). Also, providing organic EL devices with moisture sorption films and/or waterproof films prevents degradation of organic light-emitting diodes (OLEDs), which are typically easily affected by moisture.

Conventional desiccants are classifiable into chemical desiccants that undergo chemical reaction (including deliquescence) through moisture sorption, and physical desiccants that do not undergo such chemical reaction through moisture sorption. Examples of chemical desiccants include calcium oxide, calcium chloride, sodium hydroxide, potassium hydroxide, diphosphorus pentoxide, and copper sulfate, Chemical desiccants have a relatively high moisture sorption speed and a relatively high maximum moisture sorption ratio (i.e., the ratio of moisture storable in a desiccant relative to a unit mass of the desiccant in dry state). Meanwhile, examples of physical desiccants include silica gel, aluminum oxide, and zeolite. Physical desiccants undergo reversible and stable moisture sorption, and are easy to handle due to heat generation, volume change, and the like not occurring through moisture sorption. Physical desiccants are also efficient in terms of cost.

Typically, desiccants are colored, and thus scatter/absorb visible light. Accordingly, moisture sorption films containing desiccants typically have low optical transmittance. Considering this, typical moisture sorption films are not desirable for use when there is a need to visibly check the shape, the color, and/or the like of items that the moisture sorption films are used to cover. For example, this applies to when covering an OLED with a moisture sorption film and there is a need to make visible the light emitted by the OLED, when covering a building material with a moisture sorption film and there is a need to make visible the design of the building material, and when covering a food product with a moisture sorption material and there is a need to make visible the state of the food product.

In connection with this, there exists conventional technology disclosing a method of providing moisture sorption films with improved optical transmittance, by using a desiccant whose diameter is smaller than wavelengths of visible light and thus scatters/absorbs visible light by a reduced level (for example, see Patent Literature 3).

### CITATION LIST

### Patent Literature

### [Patent Literature 1]

Japanese Patent Application Publication No. 2001-68266

### [Patent Literature 2]

Japanese Patent Application Publication No, 2012-533152

### [Patent Literature 3]

Japanese Patent Application Publication No. 2003-217828

### SUMMARY OF INVENTION

### Technical Problem

However, chemical desiccants with small diameter pose problems. Specifically, with small diameter, a chemical desiccant would become excessively reactive due to an increase in total surface area per unit mass. Accordingly, such a chemical desiccant would reach saturation and lose its moisture sorption capability when exposed to air for even a short period of time. Hence, a moisture sorption film containing such a chemical desiccant brings about an increase in manufacturing cost, due to necessitating precise humidity management, moisture-resistant packing, etc., in the manufacturing process. Also, a moisture sorption film containing such a chemical desiccant is difficult to handle and thus is not suitable for practical use, due to for example necessitating immediately use of the entire amount of film manufactured upon removal of moisture-resistant packing.

Meanwhile, physical desiccants with small diameter also pose problems. Specifically, with small diameter, a physical desiccant would have destroyed moisture sorption structures, which leads to the physical desiccant having a low maximum moisture sorption ratio. Hence, a moisture sorption film containing such a physical desiccant would have a moisture sorption capability similar to that of a typical transparent resin, and as such, may not be suitable for practical use as a moisture sorption film.

In view of the above, the present invention aims to provide a moisture sorption film achieving both high optical transmittance and high suitability for practical use, and a water-resisting film and an organic EL device including such a moisture sorption film.

### Solution to Problem

One aspect of the present invention is a moisture sorption film including: a film of base material; zeolite grains dispersed in the film of base material, the zeolite grains having an average diameter of 100 nm or smaller and having a maximum moisture sorption ratio of 10 wt % or greater, wherein the moisture sorption film has a thickness of 500 nm or greater and contains the zeolite grains at an amount of 0.13 g/cm³ or greater.

### Advantageous Effects of Invention

The moisture sorption film pertaining to one aspect of the present invention achieves high optical transmittance due to containing zeolite grains with an average diameter of 100 nm or smaller. In addition, due to having a thickness of 500 nm or greater, the moisture sorption film has high flatness and achieves high optical transmittance. Further, the zeolite grains contained in the moisture sorption film have a maximum moisture sorption ratio of 10 wt % or higher, and the moisture sorption film contains the zeolite grains at an amount of 0.13 g/cm³ or greater. Accordingly, the moisture sorption film performs stable moisture sorption, can be dried, and has a higher moisture sorption capability than typical transparent resins. Hence, the moisture sorption film pertaining to one aspect of the present invention is suitable for practical use as a moisture sorption film,

### BRIEF DESCRIPTION OF DRAWINGS

FIG. 1 is a schematic perspective view of a moisture sorption film 100 pertaining to embodiment 1.

FIG. 2 is a schematic cross-sectional view taken along line \-A in FIG. 1,

FIG. 3 is a graph illustrating, for different average diameters of zeolite grains contained in moisture sorption films, a correlation between wavelengths and levels of optical transmittance.

FIG. 4 is a graph illustrating distributions of diameters of zeolite grains 102.

FIG. 5 is a schematic cross-sectional view illustrating the structure of a water-resisting film 10 pertaining to embodiment 2.

FIG. 6 is a schematic cross-sectional view illustrating the structure of an organic EL device 1 pertaining to embodiment 3.

### DESCRIPTION OF EMBODIMENTS

### Overview of Aspects of Present Invention

One aspect of the present invention is a moisture sorption film including: a film of base material; zeolite grains dispersed in the film of base material, the zeolite grains having an average diameter of 100 nm or smaller and having a maximum moisture sorption ratio of 10 wt % or greater, wherein the moisture sorption film has a thickness of 500 nm or greater and contains the zeolite grains at an amount of 0.13 g/cm³ or greater.

The moisture sorption film pertaining to one aspect of the present invention achieves high optical transmittance due to containing zeolite grains with an average diameter of 100 nm or smaller. In addition, due to having a thickness of 500 nm or greater, the moisture sorption film has high flatness and achieves high optical transmittance. Further, the zeolite grains contained in the moisture sorption film have a maximum moisture sorption ratio of 10 wt % or higher, and the moisture sorption film contains the zeolite grains at an amount of 0.13 g/cm³ or greater. Accordingly, the moisture sorption film performs stable moisture sorption, can be dried, and has a higher moisture sorption capability than typical transparent resins. Hence, the moisture sorption film pertaining to one aspect of the present invention is suitable for practical use as a moisture sorption film.

Another aspect of the present invention is the moisture sorption film pertaining to the above-described aspect of the present invention, wherein the maximum moisture sorption ratio is 15 wt % or greater. With this structure, the moisture sorption film pertaining to the above-described aspect of the present invention is provided with an extremely high moisture sorption capability, and thus is even more suitable for practical use,

Another aspect of the present invention is the moisture sorption film pertaining to the above-described aspect of the present invention, wherein the zeolite grains are produced through a build-up method or a method of first milling zeolite grains having an average diameter of 500 nm or greater and performing post-milling recrystallization.

Another aspect of the present invention is the moisture sorption film pertaining to the above-described aspect of the present invention, wherein the average diameter of the zeolite grains is no smaller than 10 nm.

Another aspect of the present invention is the moisture sorption film pertaining to the above-described aspect of the present invention, wherein the zeolite grains include zeolite grains having amorphous structures at a proportion of no greater than 20 vol %

With these structures, the moisture sorption film pertaining to the above-described aspect of the present invention contains zeolite grains having a high maximum moisture sorption ratio for maintaining their moisture sorption structures. Due to this, the moisture sorption film pertaining to the above-described aspect of the present invention is provided with a high moisture sorption capability, and thus is even more suitable for practical use.

Another aspect of the present invention is the moisture sorption film pertaining to the above-described aspect of the present invention, wherein the base material is a resin. With this structure, the moisture sorption film pertaining to the above-described aspect of the present invention can be formed easily, and has a certain level of flexibility after being formed. Thus, the moisture sorption film pertaining to the above-described aspect of the present invention is applicable to various usages.

Another aspect of the present invention is the moisture sorption film pertaining to the above-described aspect of the present invention, wherein the maximum moisture sorption ratio is no greater than 40 wt %, the thickness of the moisture sorption film is no greater than 1 mm, and the moisture sorption film contains the zeolite grains at an amount no greater than 100 wt %. With this structure, the moisture sorption film pertaining to the above-described aspect of the present invention achieves sufficient optical transmittance and is sufficiently suitable for practical use, in view of conventional moisture sorption films,

Another aspect of the present invention is a water-resisting film including: an enclosing film containing an organic material or an inorganic material and being optically transmissive, and the moisture sorption film pertaining to any one of the above-described aspects of the present invention, wherein the moisture sorption film is enclosed within the enclosing film. The water-resisting film pertaining to one aspect of the present invention is usable even in environments requiring optical transmissivity/transparency, environments requiring chronological stability, and environments with not much space.

Another aspect of the present invention is the water-resisting film pertaining to the above-described aspect of the present invention, wherein the enclosing film has a water vapor transmission rate of 1×10⁻⁵ g/(m²·day) or smaller. With this structure, the water-resisting film pertaining to the above-described aspect of the present invention is highly suitable for practical use.

Another aspect of the present invention is an organic EL device including: a base having a flat surface; at least one organic EL element disposed above the flat surface of the base; and the water-resisting film pertaining to any one of the above-described aspects of the present invention, disposed covering a top surface of the organic EL element. In the organic EL device pertaining to one aspect of the present invention, the deterioration of the organic EL element is prevented and the visibility of light emitted from the organic EL element is not interrupted. Further, the organic EL device pertaining to one aspect of the present invention is chronological stable and can be provided with reduced thickness.

Another aspect of the present invention is the organic EL device pertaining to the above-described aspect of the present invention further including the water-resisting film pertaining to any one of the above-described aspects of the present invention, disposed between the base and the organic EL element, covering a bottom surface of the organic EL element, wherein the base is a flexible organic film. With this structure, the organic EL device pertaining to the above-described aspect of the present invention achieves both flexibility and a long light-emission lifetime.

Another aspect of the present invention is the organic EL en n pertaining to the above-described aspect of the present invention further including the water-resisting film pertaining to any one of the above-described aspects of the present invention, disposed covering lateral surfaces of the organic EL element. With this structure, the organic EL device pertaining to the above-described aspect of the present invention can be provided with a thin bezel.

In the present disclosure, any term or expression related to an upward/downward direction should be construed as referring to a relatively upward/downward direction that is determined relatively according to the positional relationships between components based on an order in which layers are disposed in a multiple-layer structure, and should not be construed as referring to an absolute upward/downward direction (i.e., the vertically upward/downward direction). Accordingly, any reference to an upward/downward direction in the present disclosure does not specify an upward/downward direction in manufacture and use.

In the present disclosure, the term “film” is used to refer to a shape defined by a planar surface having a certain area and a width much smaller than the planar surface. Accordingly, the term “film” in the present disclosure does not provide any limitation regarding the object referred to as a “film”, in terms of the material of the object (i.e., whether or not the object is made of resin, fiber, etc.), the function of the object (i.e., whether or not the object is flexible, etc.), and the thickness of the object.

### Embodiment 1

With reference to the accompanying drawings, the following describes a moisture sorption film 100, which is one embodiment of the present invention.

### 1. Overall Structure of Moisture Sorption Film 100

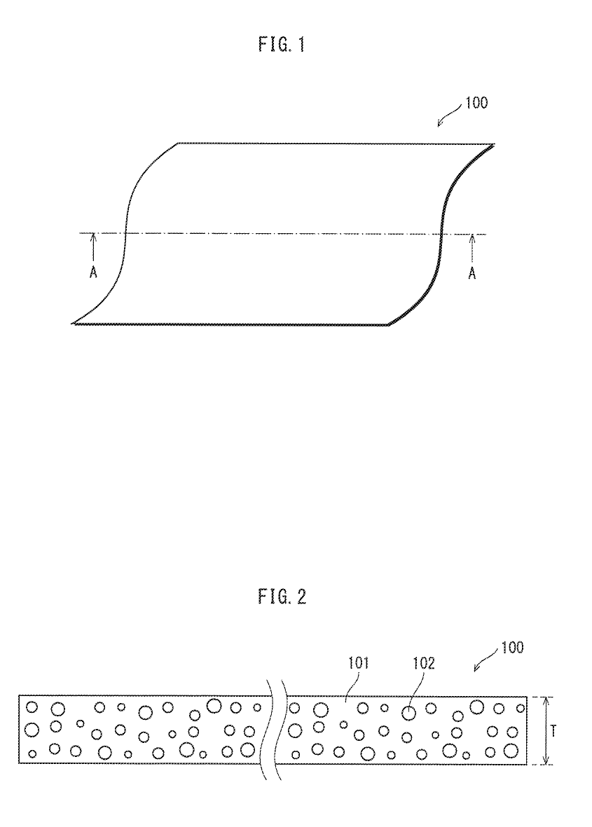

The following describes the overall structure of the moisture sorption film 100, with reference to FIG. 1 and FIG. 2. FIG. 1 is a schematic perspective view illustrating the moisture sorption film 100, and FIG. 2 is a schematic cross-sectional view taken along line A-A in FIG. 1.

The moisture sorption film 100 has flexibility, as illustrated in FIG. 1. However, the moisture sorption film 100 need not have flexibility, and may instead have high rigidity. The moisture sorption film 100 includes a base member 101 and zeolite grains 102, as illustrated in FIG. 2.

### (1) Base Member 101

The base member 101 has the shape of a film. The base member 101 is beneficially optically transmissive, and more beneficially transparent. The base member 101 is a binder that binds the zeolite grains 102 in the moisture sorption film 100. Specifically, the base member 101 is a transparent resin, such as acrylic resin, polycarbonate resin, polyethylene terephthalate resin, polyvinyl chloride resin, polystyrene resin, epoxy resin, silicone resin, or polyimide resin. Alternatively, the base member 101 may be a transparent sintered body of an yttrium aluminum garnet (YAG) ceramic or the like. As long as the base member 101 is optically transmissive as a whole, the material used for forming the base member 101 need not be transparent, or that is, a colored resin may be used for forming the base member 101.

### (2) Zeolite Grains 102

The zeolite grains 102 are grains of a desiccant, and are contained in the moisture sorption film 100 by being dispersed in the base member 101. The zeolite grains 102 may be grains of a zeolite of any type. For example, the zeolite grains 102 may be grains of LTA, FER, MWW, MFI, MOR, LTL, FAU, or BEA, which are types of zeolite specified by the International Zeolite Association.

### 2, Specifications of Moisture Sorption Film 100

### (1) Average Diameter of Zeolite Grains 102

The zeolite grains 102 have an average diameter of 100 nm or smaller. Note that typical industrial zeolite grains have diameters between 0.5 and several micrometers. Meanwhile, zeolite grains having the specific average diameter described above can be synthetically produced by, for example, building up a zeolite through hydrothermal synthesis using silica, alumina, sodium hydroxide, etc., or pulverizing an industrial zeolite.

The diameters of the zeolite grains 102 can be measured through, for example, dynamic light scattering when the zeolite grains 102 are in the form of a powder. Meanwhile, when the zeolite grains 102 have already been dispersed in the base member 101, the diameters of the zeolite grains 102 can be measured by using, for example, a scanning electron microscope (SEM) or a transmission electron microscope (TEM).

### (2) Maximum Moisture Sorption Ratio of Zeolite Grains 102

The zeolite grains 102 have a maximum moisture sorption ratio of 10 wt % or higher. In the present disclosure, the term “maximum moisture sorption ratio” is used to refer to the ratio of an adsorbable mass (in grams) of moisture relative to a single gram of zeolite in dry state. Further, a maximum moisture sorption ratio of zeolite can be measured through a method conforming to “4.1 Hydroscopicity Test” of “JIS Z 0701-1977 Silicagel Desiccants for Packaging”. However, since a maximum moisture sorption ratio of zeolite is not much dependent upon surrounding conditions such as temperature and humidity, the maximum moisture sorption ratio of the zeolite grains 102 may be measured under conditions other than those defined in “4.1 Hydroscopicity Test” of “JIS Z 0701-1977 Silicagel Desiccants for Packaging”, as long as similar measurement results are yielded.

When having the maximum moisture sorption ratio described above, the zeolite grains 102 have undestroyed moisture sorption structures and thus the zeolite grains 102 have moisture sorption capability. Typically, zeolites grains have pores that have extremely small diameters within the range of 0.2 nm to 1.0 nm, and these micropores serve as moisture sorption structures. Meanwhile, other physical desiccants, such as silica gel, aluminum oxide, and activated carbon, have pores with diameters within the range of 2 nm to 50 nm (i.e., mesopores) and/or pores with diameters of 50 nm or greater (i.e., macropores). Due to this, compared to such other physical desiccants, zeolite grains are able to maintain their moisture sorption structures to a greater extent even when having small diameters.

Further, it should be noted that even if the moisture sorption structures of zeolite are once destroyed (i.e., even if zeolite grains having amorphous structures are formed) through a process such as pulverization, the moisture sorption structures can be reformulated by recrystallizing the zeolite in a solution containing silica, alumina, and the like. Thus, it is possible to provide the zeolite grains 102 with various maximum moisture sorption ratios within a certain range, with the upper limit being the maximum moisture sorption ratio of a typical zeolite (i.e., approximately 30 wt % to 40 wt %).

As such, it is possible to produce the zeolite grains 102, which have an average diameter of 100 nm or smaller and at the same time have a maximum moisture sorption ratio of 10 wt % or higher. Further, in order to ensure that the zeolite grains 102 have moisture sorption structures, it is beneficial that the zeolite grains 102 be produced either through building up a zeolite through hydrothermal synthesis or through pulverizing a typical industrial zeolite (having an average diameter of 500 nm or greater) and then recrystallizing the zeolite.

### (3) Thickness T of Moisture Sorption Film 100

As illustrated in FIG. 2, the moisture sorption film 100 has a thickness (T) of 500 nm or greater. The thickness T of the moisture sorption film 100 can be controlled by changing certain parameters in the forming of the moisture sorption film 10, such as the amount of time film-forming is performed and application pressure. Further, when the moisture sorption film 100 is produced by processing (e.g., cutting, compressing, etching, etc.) a film prepared in advance, the processing is performed so that the thickness T of the moisture sorption film 100 is 500 nm or greater.

### (4) Amount of Zeolite Grains 102

The moisture sorption film 100 contains the zeolite grains 102 at an amount of 0.13 g/cm³ or greater. The amount of the zeolite grains 102 in the moisture sorption film 100 can be controlled by changing the mixture ratio between the base member 101 and the zeolite grains 102. Note that after the moisture sorption film 100 has been produced, the amount of zeolite grains 102 contained in the moisture sorption film 100 can be measured by utilizing the difference between the densities of the base member 101 and the zeolite grains 102. (Typically, the density of the zeolite grains 102 is greater than that of a transparent resin and smaller than that of a transparent sintered body.) Specifically, after the moisture sorption film 100 has been produced, the amount of zeolite grains 102 contained in the moisture sorption film 100 can be calculated by calculating a mixture ratio of the base material 101 and the zeolite grains 102 that provides the moisture sorption film 100 with the current density. Note that the density of the moisture sorption film 100 can be acquired by measuring the mass and the volume of the moisture sorption film 100. Further, the densities of the base material 101 and the zeolite grains 102 can be specified, for example, by specifying the specific materials thereof through analysis of physical property data, crystalline structure, and constituent chemical elements.

### (5) Notes

In the above, description is provided of a method of measuring the maximum moisture sorption ratio of the zeolite grains 102 when in the form of a powder. Meanwhile, it is also possible to calculate the maximum moisture sorption ratio of the zeolite grains 102 already contained in the moisture sorption film 100, or that is, the maximum moisture sorption ratio of the zeolite grains 102 already in the state of being dispersed in the base material 101. For example, the maximum moisture sorption ratio of the zeolite grains 102 in such a state can be calculated based on a moisture sorption ratio of the moisture sorption film 100, which is a ratio of an adsorbable mass (in grams) of moisture relative to a single gram of the moisture sorption film 100 in dry state. Specifically, the maximum moisture sorption ratio of the zeolite grains 102 contained in the moisture sorption film 100 can be calculated by multiplying the moisture sorption ratio (g/g) of the moisture sorption film 100 and the density (g/cm³) of the moisture sorption film 100, and dividing the product of the multiplication by the amount (g/cm³) of the zeolite grains 102 contained in the moisture sorption film 100.

Specifically, the moisture sorption ratio of the moisture sorption film 100 can be measured through a method conforming to “6.5 D Method” of “JIS K 7209:2000 Plastics—Determination of Water Absorption”. Further, as already discussed above, the amount (g/cm³) of the zeolite grains 102 contained in the moisture sorption film 100 can be calculated, for example, based on the densities of the moisture sorption film 100, the base material 101, and the zeolite grains 102.

### 3. Function of Moisture Sorption Film 100

### (1) Optical Transmittance

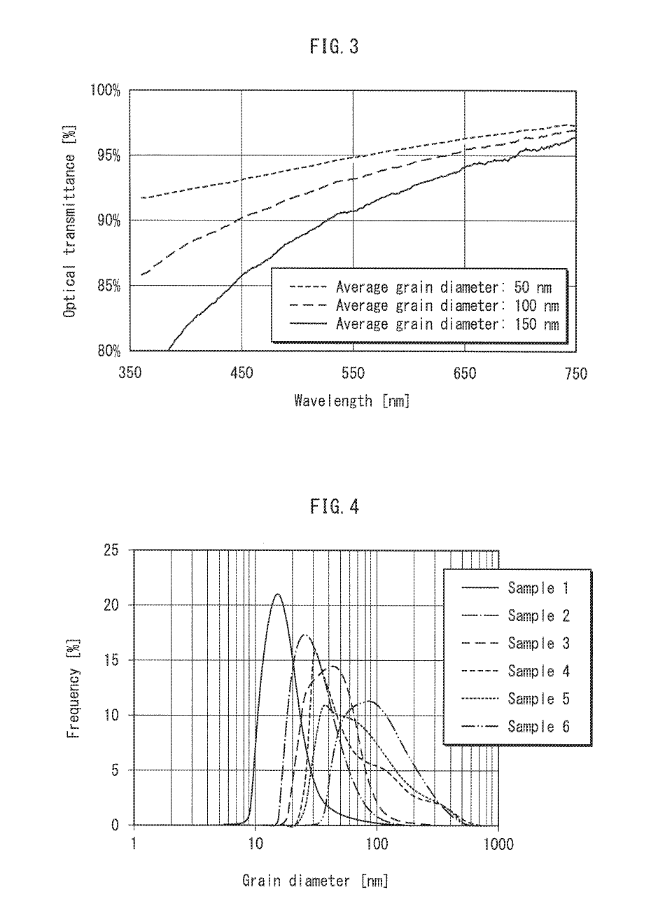

FIG. 3 is a graph illustrating, for different average diameters of zeolite grains contained in moisture sorption films, a correlation between wavelengths and levels of optical transmittance. FIG. 3 shows optical transmittance values at different wavelengths of light, for three moisture sorption films. Two of the three moisture sorption films are implementation samples of the moisture sorption film 100, one of which containing zeolite grains with an average diameter of 50 nm and the other containing zeolite grains with an average diameter of 100 nm. The last of the three moisture sorption films is a comparative sample containing zeolite grains with an average diameter of 150 nm, Note that the implementation samples and the comparative sample differed only in terms of the average diameter of zeolite grains, and had similar structures and specifications otherwise. Further, all three moisture sorption films had a thickness of 5 μm,

The comparative sample indicated a favorable optical transmittance of 90% or higher within the wavelength range between red light (approximately 700 nm) and green light (approximately 550 nm). However, the comparative sample indicated an optical transmittance of 90% or lower for the wavelength range of blue light (approximately 450 nm). Meanwhile, both implementation samples indicated a favorable optical transmittance higher than 90% for all such wavelength ranges, including the wavelength range of blue light (approximately 450 nm). Accordingly, it can be concluded that the moisture sorption film 100 achieves high optical transmittance for containing zeolite grains having an average diameter of 100 nm or smaller.

FIG. 4 is a graph illustrating distributions of diameters of zeolite grains 102. Specifically, FIG. 4 shows distributions of diameters of samples of the zeolite grains 102 (samples 1 through 6) that were prepared under different conditions but had average diameters of 100 nm or smaller. Further, Table 1 provided in the following shows diameter distribution data for each sample in a more organized state. Note that the values in Table 1 indicate grain diameters in the unit of nanometers.

TABLE 1

| Sample | 1 | 2 | 3 | 4 | 5 | 6 |
|---|---|---|---|---|---|---|
| d50 | 14.93 | 27.43 | 38.02 | 47.89 | 62 | 87 |
| d95 | 32.04 | 62.91 | 79.91 | 233.9 | 253 | 255 |
| d95/d50 | 2.1 | 2.3 | 2.1 | 4.9 | 4.1 | 2.9 |
| Average | 14.88 | 27.01 | 35.72 | 47.84 | — | — |
| d95/Average | 2.2 | 2.3 | 2.2 | 4.9 | | |

In Table 1, for each sample, “d50” indicates the diameter of a zeolite grain that was at a position corresponding to 50% among all the zeolite grains included in the sample and “d95” indicates the diameter of a zeolite grain that was at a position corresponding to 95% among all the zeolite grains included in the sample, when the zeolite grains included in the sample were arranged in order from the zeolite grain with the smallest diameter to the zeolite grain with the greatest diameter. Further, as illustrated in Table 1, in the diameter distributions of all six samples, the “d95” value was no greater than five times the “d50” value. This means that most (95%) of the zeolite grains 102 had diameters no greater than five times the median diameter (the “d50” diameter).

Turning to the moisture sorption film 100 once again, the thickness T of the moisture sorption film 100 is 500 nm or greater, and is at least five times the average diameter (100 nm or smaller) of the zeolite grains 102. This means that most of the zeolite grains 102 are enclosed inside the moisture sorption film 100, and thus, the moisture sorption film 100 has high surface flatness. Due to this, the degree of refraction/reflection of light occurring at the surface of the moisture sorption film 100 is relatively small, which means that the moisture sorption film 100 achieves relatively high optical transmittance.

In addition, when the moisture sorption film 100 is included as one of multiple layers constituting an organic EL device or the like, the moisture sorption film 100, due to having high surface flatness as described above, ensures that the layers disposed thereabove have stable quality,

The “Average” column in Table 1 lists arithmetic mean diameters for samples 1 through 4. For each of samples 1 through 4, the arithmetic mean diameter substantially equaled the median diameter (the “d50” diameter), as shown in Table 1. As such, either one of the arithmetic mean diameter and the median diameter can be used as the “average diameter” of zeolite grains 102. To support this, in the diameter distributions of the samples of zeolite grains 102, the “d95” value was no greater than five times the arithmetic mean diameter, and thus, most (95%) zeolite grains has diameters no greater than five times the arithmetic mean diameter (the “d50” diameter),

### (2) Stability and Reversibility of Moisture Sorption Capability

The moisture sorption film 100 contains the zeolite grains 102, which are grains of a physical desiccant. As such, the moisture sorption film 100 is capable of performing stable and reversible moisture sorption. Specifically, the moisture sorption film 100 is not likely to undergo chemical reaction through moisture sorption, or that is, the moisture sorption film 100 is not likely to generate heat or change in volume through moisture sorption. Due to this, the moisture sorption film 100 does not affect its surroundings through moisture sorption, and thus can be used stably. Meanwhile, typical resins undergo an increase in volume through moisture sorption. Due to this, the moisture sorption film 100 is beneficial for usages where chronological change through moisture sorption needs to be small.

Further, after moisture sorption, the moisture sorption film 100 undergoes drying (dehydration) when placed in an environment with a certain temperature, humidity, and/or pressure. Thus, the moisture sorption film 100 is suitable for practical use due to not requiring precise humidity management or moisture-resistant packing.

### (3) Moisture Sorption Capability (Moisture Sorption Density)

The moisture sorption film 100 contains the zeolite grains 102, which have a maximum moisture sorption ratio of 10 wt % or higher, at an amount of 0.13 g/cm³ or greater. Accordingly, the mass of moisture that a unit volume of the moisture sorption film 100 is capable of adsorbing (hereinafter referred to as “moisture sorption density”) is 0.013 g/cm³ or greater.

Table 2 in the following illustrates moisture sorption densities of typical transparent resins calculated from their moisture sorption ratios and densities.

TABLE 2

| | Moisture | | Moisture |
|---|---|---|---|
| | sorption | | sorption |
| | ratio | Density | density |
| Type of resin | (Wt %) | (g/cm³) | (g/cm³) |
| Acrylic resin | 0.4 | 1.2 | 0.005 |
| Polycarbonate resin | 0.15 | 1.2 | 0.002 |
| Polyethylene terephthalate | 0.2 | 1.4 | 0.003 |
| Polyvinyl chloride | 0.75 | 1.4 | 0.011 |

The moisture sorption film 100 possesses higher moisture sorption density than the typical transparent resins shown in Table 2. Further, the moisture sorption film 100 possesses higher moisture sorption density than transparent sintered bodies, which typically do not have any moisture sorption capability. This means that the moisture sorption film 100 is capable of adsorbing a greater amount of moisture than typical transparent resins, transparent sintered bodies, and the like having the same volume. This, the moisture sorption film 100 is suitable for practical use, and is particularly useful when film space is limited, such as in an organic EL device.

As described above, the moisture sorption film 100 achieves high optical transmittance and is suitable for practical use.

### 4. Notes

### (1) Wavelength Dependency of Optical Transmittance

FIG. 3 shows that, for each of the implementation samples of the moisture sorption film 100 and for the comparative sample, optical transmittance is dependent upon wavelength, within the wavelength range of visible light. Specifically, FIG. 3 shows that optical transmittance is lower at shorter wavelengths. This is considered to be due to Rayleigh scattering being superior to Mie scattering in moisture sorption films containing zeolite grains having smaller diameters than wavelengths of visible light.

Typically, Mie scattering refers to the scattering of light by particles having diameters no smaller than light wavelength. The intensity of Mie scattering is not wavelength-dependent. Meanwhile, Rayleigh scattering typically refers to the scattering of light by particles having diameters smaller than wavelength. The intensity of Rayleigh scattering is inversely proportional to the fourth power of wavelength. Accordingly, with light-scattering particles having diameters smaller than visible wavelength, optical transmittance with respect to blue light, which has relatively short wavelength, becomes relatively smaller than optical transmittance with respect to red light and green light, which have relatively long wavelength.

This means that typically, when a desiccant with small average diameter is used in a moisture sorption film to provide the moisture sorption film with high optical transmittance, the transparency quality of the moisture sorption film is impaired due to the moisture sorption film showing a base layer visible therethrough at a reddish color than its actual color. In fact, the optical transmittance of the comparative sample (containing zeolite grains with an average diameter of 150 nm) with respect to blue light was approximately 86%, whereas the optical transmittance of the comparative sample with respect to red light was approximately 94%.

However, it should be noted that the optical transmittance with respect to blue light of the implementation sample containing zeolite grains with an average diameter of 100 nm was approximately 90%, which is higher than the same for the comparative sample, while the optical transmittance of this implementation sample with respect to red light was approximately 95%, which is substantially equal to the same for the comparative sample. Thus, the optical transmittance of the implementation sample was less wavelength-dependent than the optical transmittance of the comparative sample. This result contradicts with the hypothesis that Rayleigh scattering would be more dominant in the implementation sample than in the comparative sample due to the average diameter in the implementation sample being smaller than that in the comparative sample, and shows that containing zeolite grains with an average diameter of 100 nm or smaller results not only in high optical transmittance but also high transparency quality.

Further, in FIG. 3, the line corresponding to the implementation sample containing zeolite grains with an average diameter of 50 nm is substantially linear, whereas the line corresponding to the implementation sample containing zeolite grains with an average diameter of 100 nm and the line corresponding to the comparative sample containing zeolite grains with an average diameter of 150 nm are parabolic. In other words, the line corresponding to the implementation sample containing zeolite grains with an average diameter of 50 nm indicates a lower level of wavelength-dependency. Accordingly, it can be seen that the zeolite grains 102 beneficially has an average diameter of 50 nm or smaller.

### (2) Moisture Sorption Structure

The moisture sorption film 100 contains the zeolite grains 102, which have an average diameter of 10 nm or greater.

Meanwhile, zeolite grains having an average diameter smaller than 10 nm would have diameters close to zeolite micropores, which serve as moisture sorption structures. Thus, there is a risk of such zeolite grains having a low maximum moisture sorption ratio due to including destroyed moisture sorption structures.

In the moisture sorption film 100, the proportion of zeolite grains 102 having destroyed hydroscopic structures (i.e., micropores), or that is, the proportion of zeolite grains 102 with amorphous structures, is beneficially 30 vol % or less, and more beneficially 20 vol % or less. When the proportion of zeolite grains 102 having amorphous structures is within this range, the zeolite grains 102 as a whole secure a sufficient maximum moisture sorption ratio. For example, the proportion of zeolite grains 102 having amorphous structures can be assessed through X-ray powder diffraction using an X-ray diffraction (XRD) device, Specifically, the X-ray diffraction pattern of grains of a conventional zeolite having a structure similar to the zeolite grains 102 can be used to confirm an incident angle and a peak area of a crystalline structure of the conventional zeolite. Further, by comparing this incident angle and peak area respectively with an incident angle and a peak area of the zeolite grains 102 in an X-ray diffraction pattern of the zeolite grains 102, the proportion of zeolite grains 102 having amorphous structures can be assessed.

In the moisture sorption film 100, the zeolite grains 102 beneficially contain an alkaline earth metal element such as calcium or magnesium. Typically, alkaline metal elements and alkaline earth metal elements serve as network modifiers that stabilize the networks of silicates such as zeolite. Here, since network modifiers form ionic bonds, alkaline earth metal elements, which have a valence of 2, have a stronger function of network stabilization than alkaline metal elements, which have a valence of 1. Accordingly, containing an alkaline earth metal element in the zeolite grains 102 allows moisture sorption structures to be formed or maintained even with small diameters, and as such, ensures that the zeolite grains 102 achieve a sufficient maximum moisture sorption ratio,

### (3) Other Issues

The zeolite grains 102 further beneficially have a maximum moisture sorption ratio of 15 wt % or higher. In this case, the moisture sorption film 100 has a moisture sorption density of approximately 0.020 g/cm³ or greater, which is at least twice the moisture sorption density of typical transparent resins. Accordingly, the moisture sorption film 100 would have an extremely high moisture sorption capability, and would be even more suitable for practical use.

Beneficially, the base member 101 is a resin. This facilitates the forming of the moisture sorption film 100. Further, this provides the moisture sorption film 100 having been formed with a certain level of flexibility, and thus diversifies the usage of the moisture sorption film 100. Note that the base member 101 is not limited to being a transparent resin or a transparent sintered body as described above, and may for example be solely composed of zeolite grains having an average diameter of 100 nm or smaller. Such zeolite grains have optical transmittance and can be put into a film shape. Further, the zeolite grains 102 can be dispersed in such zeolite grains. As such, such zeolite rains qualify as one form of the base material 101. Thus, it can be said that the moisture sorption film 100 contains zeolite grains at an amount of 100 wt % or less, and further, when the moisture sorption film 100 contains zeolite grains at the amount of 100 wt %, the base material 101 is solely composed of the zeolite grains.

The thickness T of the moisture sorption film 100 is beneficially 1 mm or smaller, and more beneficially 200 μm or smaller, and yet more beneficially 50 μm or smaller. With such thickness, the moisture sorption film 100 exhibits prominently high moisture sorption capability.

The moisture sorption film 100 need not have a self-contained structure. That is for example, the moisture sorption film 100 may be disposed on a base layer to be integrated with the base layer.

### Embodiment 2

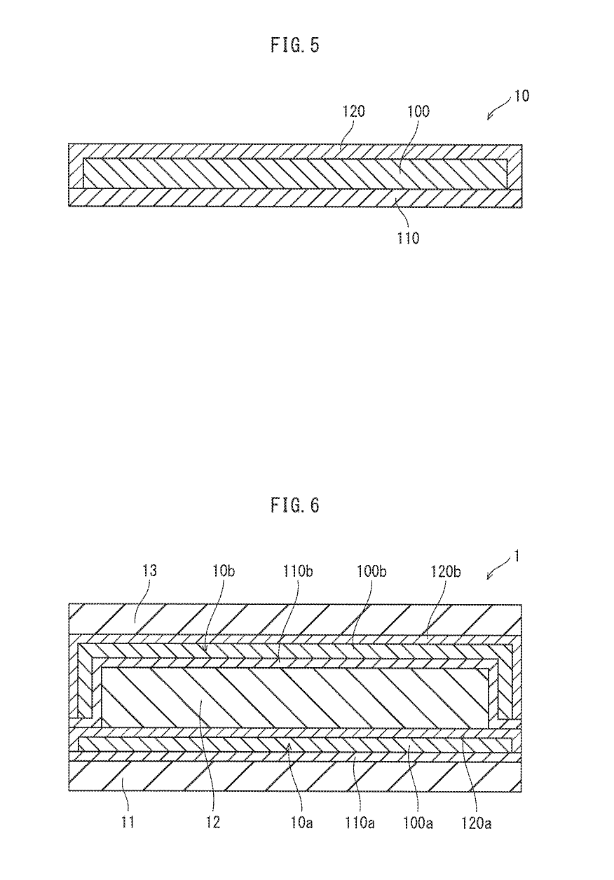

With reference to FIG. 5, the following describes a water-resisting film 10, which is one embodiment of the present invention. FIG. 5 is a schematic cross-sectional view illustrating the structure of the water-resisting film 10.

### 1. Overall Structure of Water-Resisting Film 10

The water-resisting film 10 is resistant to penetration by moisture. The water-resisting film 10 includes the moisture sorption film 100 pertaining to embodiment 1, a first enclosing film 110, and a second enclosing film 120. The moisture sorption film 100 is not described in detail in the following.

Each of the first enclosing film 110 and the second enclosing film 120 is optically transmissive, or more beneficially transparent, and contains an organic material or an inorganic material. In the water-resisting film 10, the first enclosing film 110 and the second enclosing film 120 resist penetration by moisture existing in the surroundings and in the moisture sorption film 100. Each of the first enclosing film 110 and the second enclosing film 120, when containing an organic material, is an organic film of, for example, polyethylene terephthalate, polyethylene naphthalate, diacetyl cellulose, triacetyl cellulose (TAC) and the like, poly-methyl methacrylate, polystyrene, acrylonitrile-styrene co-polymers, polyethylene, polypropylene, poly-olefins having cyclic and norbornene structures, ethylene-propylene co-polymers, nylons and aromatic polyamides, imide polymers, sulfone polymers, polyether sulfone polymers, polyetheretherketone polymers, polyphenylene sulfide polymers, vinyl alcohol polymers, vinylidene chloride polymers, vinyl butyral polymers, arylate polymers, polyoxymethylene polymers, and epoxy polymers. Further, each of the first enclosing film 110 and the second enclosing film 120 may be a film containing two or more of such organic materials. Alternatively, each of the first enclosing film 110 and the second enclosing film 120, when containing an inorganic material, is for example, a transparent, electrically-insulative inorganic film of silicon nitride, silicon oxide, silicon oxynitride, or the like, or a transparent, electrically-conductive inorganic film of indium tin oxide, indium zinc oxide (IZO), or the like. Further, each of the first enclosing film 110 and the second enclosing film 120 may be a film containing two or more of such inorganic materials. Further, each of the first enclosing film 110 and the second enclosing film 120 need not be composed of a single layer, and may be a combination of two or more different films.

In the water-resisting film 10, the moisture sorption film 100 is disposed on the first enclosing film 110, and has the top surface thereof covered by the second enclosing film 120. Further, the lateral surfaces of the moisture sorption film 100 are also beneficially covered by the second enclosing film 120. When the lateral surfaces of the moisture sorption film 100 are also covered by the second enclosing film 120, the moisture sorption film 100 is enclosed by the first enclosing film 110 and the second enclosing film 120.

### 2. Function of Water-Resisting Film 10

Due to having the structure described above, the water-resisting film 10 has a stronger effect of resisting the penetration by moisture compared to any of an organic film, an inorganic film, a moisture sorption film, or the like used alone. Specifically, organic and inorganic films are inevitably produced to have deficiencies arising from their production process. Due to having such deficiencies, organic and inorganic films, when used alone, cannot completely resist penetration by moisture, or in other words, allow a certain amount of moisture to penetrate therethrough. Meanwhile, with the water-resisting film 10, moisture having penetrated through the first enclosing film 110 and the second enclosing film 120 is adsorbed by the moisture sorption film 100. Due to this, the water-resisting film 10 is capable of resisting penetration of moisture until the moisture sorption film 100 reaches saturation.

Further, the moisture sorption film 100, when used alone, directly adsorbs moisture existing in the surroundings from surfaces thereof, and as such, quickly reaches saturation. Meanwhile, included in the water-resisting film 10, the moisture sorption film 100 adsorbs only moisture having penetrated through the first enclosing film 110 and the second enclosing film 120. Thus, the moisture sorption film 100, when included in the water-resisting film 10, reaches saturation after a longer amount of time and thus functions as a moisture sorption film fix an extended amount of time,

Further, the water-resisting film 10 includes the moisture sorption film 100, which achieves high optical transmittance, stable and reversible moisture sorption, and high moisture sorption capability (i.e., has a high moisture sorption density). Accordingly, the water-resisting film 10 also achieves high optical transmittance and stable and reversible moisture sorption, and also achieves high water-resisting capability while having small thickness. Thus, the water-resisting film. 10 is usable even in environments requiring optical transmissivity/transparency, environments requiring chronological stability, and environments with not much space,

### 3. Notes

Each of the first enclosing film 110 and the second enclosing film 120 is beneficially made by using a material having a dense structure and not allowing ranch moisture, oxygen, and the like to pass through. Specifically, each of the first enclosing film 110 and the second enclosing film 120 beneficially has a water vapor transmission rate (WVTR) of 1×10⁻⁵ g/(m²·day) or lower, as defined in “JIS K 7129: 2008 Plastics—Film and sheeting—Determination of water vapor transmission rate—Instrumental method”. The water-resisting film 10, in which the first enclosing film 110 and the second enclosing film 120 satisfy this condition, yielded meaningful results in an experiment described in detail in the following, and is highly suitable for practical use.

Further, in the water-resisting film 10, the first enclosing film 110 and the second enclosing film 120 are two separate films. However, the moisture sorption film 100 may be enclosed within a single enclosing film. Alternatively, each of the top, the bottom, and the lateral surfaces of the moisture sorption film 100 may be covered by a separate film. Further, a given surface (the top, the bottom, or one of the lateral surfaces) of the moisture sorption film 100 need not be covered by using a single enclosing film, and may be covered by using two or more separate enclosing films. However, it should be noted that the smaller the number of interfaces between enclosing films around the moisture sorption film 100 the more beneficial, because an interface between enclosing films typically is likely to allow moisture to pass therethrough.

The water-resisting film 10 need not have a self-contained structure. That is for example, the water-resisting film 10 may be disposed on a base layer, and may be composed of the first enclosing film 110, the moisture sorption film 100, and the second enclosing film 120 disposed in the stated order.

### Embodiment 3

With reference to FIG. 6, the following describes an organic EL device 1, which is one embodiment of the present invention. FIG. 6 is a schematic cross-sectional view illustrating the organic EL device 1.

### 1. Overall Structure of Organic EL Device 1

The organic EL device 1 is a light-emitting device making use of an electroluminescent effect of an organic compound. The organic EL device 1 is, for example, an organic EL display device or an organic EL lighting device. The organic EL device 1 includes water-resisting films 10a and 10b, each of which corresponds to the water-resisting film 10 pertaining to embodiment 2. The organic EL device 1 further includes a base 11, an organic EL layer 12, and a sealing member 13. The water-resisting film 10a includes a moisture sorption film 100a, a first enclosing film 110a, and a second enclosing film 120a. The water-resisting film 10b includes a moisture sorption film 100b, a first enclosing film 110b, and a second enclosing film 120b. Each of the moisture sorption films 100a and 100b corresponds to the moisture sorption film 100, each of the first enclosing films 110a and 110b corresponds to the first enclosing film 110, and each of the second enclosing films 120a and 120h corresponds to the second enclosing film 120.

The following describes the respective components. The water-resisting films 10a and 10h are not described in detail in the following.

### (1) Base 11

The base 11 is a component having the shape of a flat plate. The base 11 supports components of the organic EL device 1 that are stacked thereon. Further, the base 11 serves as a base layer for the water-resisting film 10a. Specifically, the water-resisting film 10a is disposed on a main surface of the base 11. The base 11 may be formed by using an electrically-insulative material or a semiconductor material such as silicon. Alternatively, the base 11 may be formed by using a metal material (e.g., aluminum or stainless) coated with an electrically-insulative material.

Examples of electrically-insulative materials include resins such as an acrylic resin, styrenic resin, polycarbonate resin, epoxy resin, polyethylene resin, polyester resin, polyimide resin, and silicone resin. Other examples of electrically-insulative materials include glass materials such as soda glass, quartz glass, and borosilicate glass, and metal oxides such as aluminum oxide,

Beneficially, the base 11 either has optical reflectivity or optical transmissivity, depending upon the direction in which light is to be taken out from the organic EL device 1.

### (2) Organic EL Layer 12

The organic EL layer 12 is disposed on the water-resisting film 10a, or that is, above the main surface of the base 11. The organic EL layer 12 includes at least one OLED therein, and is covered by the water-resisting film 10b. For example, when the organic EL device 1 is an organic EL display device, the organic EL layer 12 includes a plurality of OLEDs that are arranged two dimensionally along the main surface of the base 11. Alternatively, when the organic EL device 1 is for example an organic EL lighting device, the organic EL layer 12 includes one or more OLEDs extending across the entire organic EL layer 12. In any case, the organic EL device 1 has at least one OLED disposed above the main surface of the base IL

Also, when the organic EL device 1 is an organic EL display device of the active matrix type, the organic EL layer 12 further includes thin film transistors (TFTs) that drive the OLEDs. Further, the organic EL layer 12 may further include, for example, a bank that separates the OLEDs from each other. Such components of the organic EL layer 12 (e.g., the OLEDs, the TFTs, and the bank) may be formed by using conventional material.

### (3) Sealing Member 13

The sealing member 13 protects the organic EL layer 12 and the water-resisting film 10b from physical impact and the like, and is disposed on the water-resisting film 10b. The sealing member 13 can be formed by using the same material as the base 11. Further, the sealing member 13 beneficially is a flexible organic film, similar to the base 11. Beneficially, the sealing member 13 either has optical reflectivity or optical transmissivity, depending upon the direction in which light is to be taken out from the organic EL device 1.

### 2. Effects of Structure of Organic EL Device 1

In the organic EL device 1, the water-resisting film 10a is disposed between the base 11 and the organic EL layer 12, covering a bottom surface of the organic EL layer 12. Further, the water-resisting film 10b is disposed covering a top surface and lateral surfaces of the organic EL layer 12. That is, the organic EL layer 12 is sealed with the water-resisting s 10a and 10b.

Typically, OLEDs easily deteriorate when coming into contact with moisture. However, in the organic EL device 1, OLEDs are sealed with the water-resisting films 10a and 10b, which have high optical transmittance. Due to this, the deterioration of the OLEDs is prevented and the visibility of light emitted from the OLEDs is not interrupted. Further, the water-resisting films 10a and 10b are not likely to generate heat or change in volume through moisture sorption. Due to this, the organic EL device 1 has chronological stability. In addition, the water-resisting films 10a and 10b achieve high water-resisting capability while having small thickness. Thus, the organic EL device 1 can be configured to have small thickness.

### 3. Notes

In the organic EL device 1, due to the water-resisting film 10a being disposed on the base 11, the base 11 itself need not have water-resisting capability. Accordingly, the base 11 can be configured by using a flexible film such as a film of an organic material, one example of which is resin, Thus, the organic EL device 1 can achieve both flexibility and a long light-emission lifetime.

Further, the organic EL device 1 achieves high light-emission efficiency of the OLEDs for including the moisture sorption films 100a and 100b. Typically, light-emission efficiency of an OLED is limited due to the light-emission efficiency of blue light becoming a bottle neck. However, due to the moisture sorption films 100a and 100b containing zeolite grains 102 with an average diameter of 100 nm or smaller, the moisture sorption films 100a and 100b have high optical transmittance particularly with respect to blue light. Accordingly, the organic EL device 1 has high overall light-emission efficiency, due to blue light, which limits light-emission efficiency as described above, being emitted from the organic EL device 1 at high efficiency. Here, note that when the organic EL device 1 includes OLEDs emitting light of different colors, it is particularly beneficial that the moisture sorption films 100a and 100b contain zeolite grains 102 with an average diameter of 50 nm or smaller. That is, with zeolite grains 102 with an average diameter of 50 nm or smaller, the wavelength dependency of optical transmittance is substantially linear, as illustrated in FIG. 3. Thus, this configuration facilitates adjusting luminance levels of OLEDs of different light-emission colors.

In the organic EL device 1, a single water-resisting film (i.e., the water-resisting film 10b) covers both the top surface and the lateral surfaces of the organic EL layer 12. However, the water-resisting film 10b need not cover the lateral surfaces of the organic EL layer 12, as long as it covers the top surface of the organic EL layer 12. When the water-resisting film 10b does not cover the lateral surfaces of the organic EL layer 12, the lateral surfaces of the organic EL layer 12 may be covered by using the water-resisting film 10 pertaining to embodiment 2, or by using a curable resin containing a desiccant. Nevertheless, covering lateral surfaces of an organic EL layer (e.g., the organic EL layer 12) with a thin water-resisting film having high water-resisting capability (e.g., the water-resisting film 10) provides an organic EL device (e.g., the organic EL device 1) with a thin sealing structure at lateral surface sides, or in other words, a thin bezel. Note that in this case, a single water-resisting film (i.e., the water-resisting film 10) may cover all of the top, the bottom, and the lateral surfaces of the organic EL layer 12.

In the organic EL device 1, the water-resisting films 10a and 10b are in direct contact with the organic EL layer 12. However, the water-resisting films 10a and 10b need not be in direct contact with the organic EL layer 12, or that is, another component may be disposed between the organic EL layer 12 and each water-resisting film.

The organic EL device 1 includes the sealing member 13, but the sealing member 13 need not be included.

In the organic EL device 1, every surface of the organic EL layer 12 is covered with a water-resisting film (i.e., the water-resisting films 10a and 10b). However, not every surface of the organic EL layer 12 needs to be covered with a water-resisting film, and for example, a modification may be made of forming the base 11 by using a material such as glass not allowing much moisture to pass through, and of covering only the top and lateral surfaces of the organic EL layer 12 with a water-resisting film.

In the organic EL device 1, the bottom and lateral surfaces of the organic EL layer 12 are covered with a water-resisting film having high optical transmittance (i.e., the water-resisting films 10a and 10b). However, not both the bottom and lateral surfaces of the organic EL layer 12 need to be covered with such a water-resisting film, and it suffices for such a water-resisting film to be at least disposed to cover a side of the organic EL layer 12 in the direction in which light is taken out from the organic EL device 1. Meanwhile, the side of the organic EL layer 12 opposite the direction in which light is taken out from the organic EL device 1 may be covered with a water-resisting film having relatively low optical transmittance.

The organic EL device 1 described in embodiment 3 includes OLEDs, which are organic EL elements that easily deteriorate when coming in contact with moisture. However, the moisture sorption film 100 and the water-resisting film 10 need not be used in such an organic EL device. For example, the moisture sorption film 100 may be used to cover and thus protect an electric circuit element such as an oxide TFT, an organic TFT, a battery element, or a photoelectric conversion element, a food product, etc. For example, the moisture sorption film 100 may be used for controlling humidity within a building by being disposing to cover a lateral surface of a wall material or a fitting, or may be used for controlling humidity within a package by being disposed within a package of a food product or the like.

### <Evaluation of Light-Emission Lifetime of Organic EL Device 1>

The following describes the results of an evaluation of light-emission lifetime, performed by preparing implementation samples of the organic EL device 1 pertaining to embodiment 3. Note that the results described in the following serve as evaluations of moisture adsorption capabilities of implementation samples of the moisture sorption film pertaining to embodiment 1 and water-resisting capabilities of implementation samples of the water-resisting film 10 pertaining to embodiment 2.

### 1. Specifications of Organic EL Devices

The following describes the specifications of the sample organic EL devices used for the evaluation. Each sample had the structure of the organic EL device 1 illustrated in FIG. 6. Further, each sample was configured to include moisture sorption films 100a and 100b each having a thickness of 500 nm, and in each sample, the moisture sorption films 100a and 100b contained zeolite grains 102 at an amount of 0.13 g/cm³. Further, in each sample, the first enclosing films 110a and 110b and the second enclosing films 120a and 120b were silicon nitride films having a water vapor transmission rate of 1×10⁻⁵ g/(m²·day),

For the evaluation, two implementation samples were prepared. In one implementation sample (referred to in the following as implementation sample 1), the moisture sorption films 100a and 100b contained zeolite grains 102 having a maximum moisture sorption ratio of 10 wt %. In the other implementation sample (referred to in the following as implementation sample 2), the moisture sorption films 100a and 100h contained zeolite grains 102 having a maximum moisture sorption ratio of 15 wt %. In addition, a comparative sample was prepared, having the same structure and specifications as implementation samples 1 and 2 except for containing zeolite grains having a maximum moisture sorption ratio of 5 wt %

### 2. What was Evaluated

In the evaluation, the above-described organic EL sample devices were placed in a high temperature/humidity environment where the temperature was 60° C. and the humidity was 90%. Further, OLEDs of the organic EL sample devices were caused to emit light continuously for a period of one thousand hours, and after the elapse of this period, it was observed whether or not dark spots were present at the light-emitting surfaces of the OLEDs. Typically, a dark spot is a portion of an OLED light-emitting surface having undergone deterioration through contact with moisture. Thus, dark spots in an OLED light-emitting surface indicate that at such portions of the OLED light-emitting surface, the moisture sorption film is not capable of adsorbing any more moisture and the water-resisting film is not capable of resisting any more moisture. Note that the evaluation, performed under the conditions described above, is an accelerated life testing corresponding to the same evaluation performed under an environment where temperature is 25° C. and humidity is 50%, over twenty-times the period of time, and corresponds to an evaluation of whether or not the sample devices have a light-emission lifetime of approximately two years.

### 3. Evaluation Results

Table 3 illustrates the evaluation results.

TABLE 3

| | | | Maximum | |
|---|---|---|---|---|
| | | | moisture | |
| | Film | | sorption | Evaluation |
| | thickness | Content | ratio | result |
| Comparative | 500 nm | 0.13 g/cm³ | 5 wt % | NO GOOD |
| sample | | | | |
| Implementation | 500 nm | 0.13 g/cm³ | 10 wt % | GOOD |
| sample 1 | | | | |
| Implementation | 500 nm | 0.13 g/cm³ | 15 wt % | VERY GOOD |
| sample 2 | | | | |

As illustrated in Table 3, dark spots with visible size were observed in the light-emitting surface of the comparative sample. Meanwhile, in implementation sample 1, while dark spots recognizable when magnified were observed, dark spots with visible size were not observed. Thus, implementation sample 1 had acceptable light-emission quality. Meanwhile, no dark spots were recognizable even when implementation sample 2 was magnified, and thus, no dark spots were observed in implementation sample 2,

These evaluation results prove that the organic EL device 1 has a light-emitting lifetime of approximately two years under practical conditions of use. Further, these evaluation results prove that the moisture sorption film 100 and the water-resisting film 10 are useful under practical conditions of use. In the above-described evaluation, it is observed whether an organic EL device emitted or did not emit light merely to evaluate moisture penetration level. However, this evaluation also serves as an evaluation of the moisture sorption capability of the moisture sorption film 100 when not included in an organic EL device and the water-resisting capability of the water-resisting film 10 when not included in an organic EL device. That is, the evaluation proves that the moisture sorption film 100 and the water-resisting film 10 are suitable for practical use.

### INDUSTRIAL APPLICABILITY

The moisture sorption film and the water-resisting film pertaining to the present invention are widely useful as, for example, components of electronic devices, building materials, food products, etc., and packaging material for electronic devices, building materials, food products, etc. Further, the organic EL device pertaining to the present invention is widely useful in devices such as television devices, commercial displays, personal computers, and portable electronic devices, and various other electronic devices having display functions.

### REFERENCE SIGNS LIST

1 organic EL device
10, 10a, 10b water-resisting film
11 base
12 organic EL layer
100, 100a, 100b moisture sorption film
101 base member
102 zeolite grains
110, 110a, 110b first enclosing film
120, 120a, 120b second enclosing film
T thickness

1. A moisture sorption film comprising:
a film of base material;
zeolite grains dispersed in the film of base material, the zeolite grains having an average diameter of 100 nm or smaller and having a maximum moisture sorption ratio of 10 wt % or greater, wherein
the moisture sorption film has a thickness of 500 nm or greater and contains the zeolite grains at an amount of 0.13 g/cm³ or greater.

2. The moisture sorption film of claim 1, wherein
the maximum moisture sorption ratio is 15 wt % or greater.

3. The moisture sorption film of claim 1, wherein
the zeolite grains are produced through a build-up method or a method of first milling zeolite grains having an average diameter of 500 nm or greater and performing post-milling recrystallization.

4. The moisture sorption film of claim 1, wherein
the average diameter of the zeolite grains is no smaller than 10 nm.

5. The moisture sorption film of claim 1, wherein
the zeolite grains include zeolite grains having amorphous structures at a proportion of no greater than 20 vol %.

6. The moisture sorption film of claim 1, wherein
the base material is a resin.

7. The moisture sorption film of claim 1, wherein
the maximum moisture sorption ratio is no greater than 40 wt %,
the thickness of the moisture sorption film is no greater than 1 mm, and
the moisture sorption film contains the zeolite grains at an amount no greater than 100 wt %.

8. A water-resisting film comprising:
an enclosing film containing an organic material or an inorganic material and being optically transmissive, and
the moisture sorption film of claim 1, wherein
the moisture sorption film is enclosed within the enclosing film.

9. The water-resisting film of claim 8, wherein
the enclosing film has a water vapor transmission rate of 1×10⁻⁵ g/(m²·day) or smaller.

10. An organic electroluminescence (EL) device comprising:
a base having a flat surface;
at least one organic EL element disposed above the flat surface of the base; and
the water-resisting film of claim 8, disposed covering a top surface of the organic EL element.

11. The organic EL device of claim 10 further comprising
the water-resisting film of claim 8, disposed between the base and the organic EL element, covering a bottom surface of the organic EL element, wherein
the base is a flexible organic film.

12. The organic EL device of claim 10 further comprising
the water-resisting film of claim 8, disposed covering lateral surfaces of the organic EL element.

13. The organic EL device of claim 11 further comprising
the water-resisting film of claim 8, disposed covering lateral surfaces of the organic EL element.
